(19) United States
(12) Patent Application Publication
(10) Pub. No.: US 2016/0087582 A1
(43) Pub. Date: Mar. 24, 2016

(54) RC OSCILLATOR

(71) Applicant: QUALCOMM Incorporated, San Diego, CA (US)

(72) Inventor: Lennart Karl-Axel MATHE, San Diego, CA (US)

(21) Appl. No.: 14/492,495

(22) Filed: Sep. 22, 2014

(51) Int. Cl. H03B 5/24

(52) U.S. Cl. CPC H03B 5/24

(57) ABSTRACT

An oscillator includes an oscillating circuit having an input and an output configured to oscillate between a first state and a second state. The oscillating circuit includes a resistor-capacitor circuit configured to bias the oscillating circuit input towards a target voltage. The oscillating circuit is configured to transition the oscillating circuit output from the first state to the second state in response to the oscillating circuit input reaching a threshold voltage before it reaches the target voltage. Another oscillator includes an oscillating circuit having an input and an output configured to oscillate between the first state and the second state. The oscillating circuit is configured to transition the oscillating circuit output from the first state to the second state in response to the oscillating circuit input reaching a threshold voltage. A starting circuit is configured to set the oscillating circuit input to the threshold voltage to start the oscillating circuit.

### BACKGROUND

1. Field

The present disclosure relates generally to electronic circuits, and more particularly, to a resistance-capacitance (RC) oscillator.

2. Background

An oscillator finds applications in numerous electronic apparatuses including, e.g., wireless devices. A wireless device (e.g., a cellular phone or a smartphone) may transmit and receive data for two-way communication with a wireless communication system. The wireless device may include a transmitter for data transmission and a receiver for data reception. Moreover, the wireless device have grown in complexity and now commonly include multiple processors (e.g., baseband processor and application processor) and other resources that allow mobile device users to execute complex and power intensive software applications (e.g., music players, web browsers, video streaming applications, etc.).

As an example, the oscillator may be used to generate various clocks used in the wireless device. For example, the oscillator may be used to generate a processor clock for operating the baseband processor or the application processor. Each of the processors may further include oscillators to generate clocks for portions of the processor. In the example set forth above, the operations of the processors may depend on the oscillator to provide a consistent and accurate oscillating signal. An RC oscillator generates an oscillating signal at a frequency based on an RC constant. Compared to other types of oscillators, the RC constant (and therefore the frequency) of RC oscillators is easier to adjust, and may be more constant over voltage, process, and temperature variations.

### SUMMARY

Aspects of an oscillator are disclosed. The oscillator includes an oscillating circuit having an input and an output configured to oscillate between a first state and a second state. The oscillating circuit includes a resistor-capacitor circuit configured to bias the oscillating circuit input towards a target voltage. The oscillating circuit is configured to transition the oscillating circuit output from the first state to the second state in response to the oscillating circuit input reaching a threshold voltage before the oscillating circuit input reaches the target voltage.

Aspects of another oscillator are disclosed. The oscillator includes an oscillating circuit having an input and an output configured to oscillate between the first state and the second state. The oscillating circuit is configured to transition the oscillating circuit output from the first state to the second state in response to the oscillating circuit input reaching a threshold voltage. A starting circuit configured to set the oscillating circuit input to the threshold voltage to start the oscillating circuit.

Aspects of a method for operating an oscillating circuit are disclosed. The method includes oscillating between a first state and a second state at an oscillating circuit output. The method further includes biasing an oscillating circuit input towards a target voltage. The oscillating between the first state and the second state includes transitioning the oscillating circuit output from the first state to the second state in response to the oscillating circuit input reaching a threshold voltage before the oscillating circuit input reaches the target voltage.

Aspects of a method for operating an oscillating circuit are disclosed. The method includes oscillating between a first state and a second state at an oscillating circuit output. The oscillating between the first state and the second state includes transitioning the oscillating circuit output from the first state to the second state in response to an oscillating circuit input reaching a threshold voltage. The method further includes setting the oscillating circuit input to the threshold voltage to start the oscillating between the first state and the second state.

It is understood that other aspects of apparatus, circuits and methods will become readily apparent to those skilled in the art from the following detailed description, wherein various aspects of apparatus, circuits and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus, circuits and methods will now be presented in the detailed description by way of example, and not by way of limitation, with reference to the accompanying drawings, wherein:

FIG. 1 is a conceptual block diagram illustrating a wireless device, within which an exemplary embodiment may be included.

FIG. 2 is a block diagram illustrating a wireless transceiver, within which an exemplary embodiment may be included.

FIG. 3 is a functional block diagram illustrating an exemplary embodiment of an RC oscillator.

FIG. 4 is a circuit diagram illustrating an exemplary embodiment of an RC oscillator.

FIG. 5 is a diagram of waveforms of an exemplary embodiment of an RC oscillator in operation.

FIG. 6 is a flowchart of an exemplary embodiment of an RC oscillator in operation.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus, circuit or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the terms “comprises”, “comprising,”, “includes” and/or “including”, when used herein, specify the presence of the stated features, integers, steps, operations, elements, and/or components, but do not preclude the presence or addition of one or more other features, integers, steps, operations, elements, components, and/or groups thereof

Various aspects of an RC oscillator will now be presented. While the embodiments of the RC oscillator are presented in reference to wireless communication applications, as those skilled in the art will readily appreciate, such aspects may be extended to other applications and devices. By way of example, various aspects of the present invention may be used in applications where an oscillating signal starts to oscillate at a target oscillating frequency. Such applications may include an imager or ultrasonic imager where the oscillator turns on and off precisely in synchronization with an asynchronous signal (e.g., operating without clocks). Persons of ordinary skill in the art would readily recognize that aspects of the RC oscillator would find uses in a wide differential of applications.

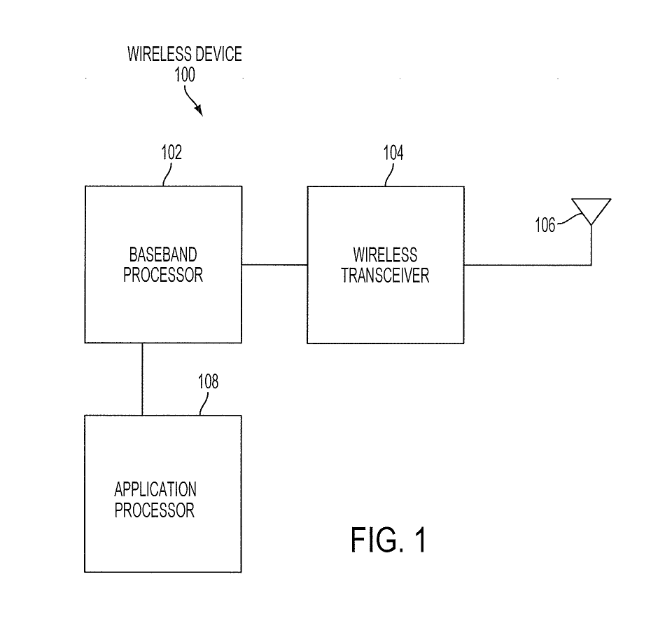

FIG. 1 is a conceptual block diagram illustrating a wireless device, within which an exemplary embodiment may be included. The wireless device 100 may be configured to support any suitable multiple access technology, including by way of example, Code Division Multiple Access (CDMA) systems, Multiple-Carrier CDMA (MCCDMA), Wideband CDMA (W-CDMA), High-Speed Packet Access (HSPA, HSPA+) systems, Time Division Multiple Access (TDMA) systems, Frequency Division Multiple Access (FDMA) systems, Single-Carrier FDMA (SC-FDMA) systems, Orthogonal Frequency Division Multiple Access (OFDMA) systems, or other multiple access technologies. The wireless device 100 may be further configured to support any suitable air interface standard, including by way of example, Long Term Evolution (LTE), Evolution-Data Optimized (EV-DO), Ultra Mobile Broadband (UMB), Universal Terrestrial Radio Access (UTRA), Global System for Mobile Communications (GSM), Evolved UTRA (E-UTRA), IEEE 802.11 (Wi-Fi), IEEE 802.16 (WiMAX), IEEE 802.20, Flash-OFDM, Bluetooth, or any other suitable air interface standard. The actual air interface standard and the multiple access technology supported by the wireless device 100 will depend on the specific application and the overall design constraints imposed on the system.

The wireless device 100 includes a baseband processor 102, a wireless transceiver 104, and an antenna 106. The wireless transceiver 104 may employ various aspects of phase locked loops presented throughout this disclosure to generate one or more LO signals to support both a transmitting and receiving function. The wireless transceiver 104 performs the transmitting function by modulating one or more carrier signals with a data generated by the baseband processor 102 for transmission over a wireless channel through the antenna 106. The wireless transceiver 104 performs a receiving function by demodulating one or more carrier signals received from the wireless channel through the antenna 106 to recover data for further processing by the baseband processor 102. The baseband processor 102 provides the basic protocol stack required to support wireless communications, including for example, a physical layer for transmitting and receiving data in accordance with the physical and electrical interface to the wireless channel, a data link layer for managing access to the wireless channel, a network layer for managing source to destination data transfer, a transport layer for managing transparent transfer of data between end users, and any other layers necessary or desirable for establishing or supporting a connection to a network through the wireless channel. The baseband processor 102 communicates with the application processor 108, which is configured to run the various applications of the wireless device 100 (e.g., music players, web browsers, video streaming applications, etc.).

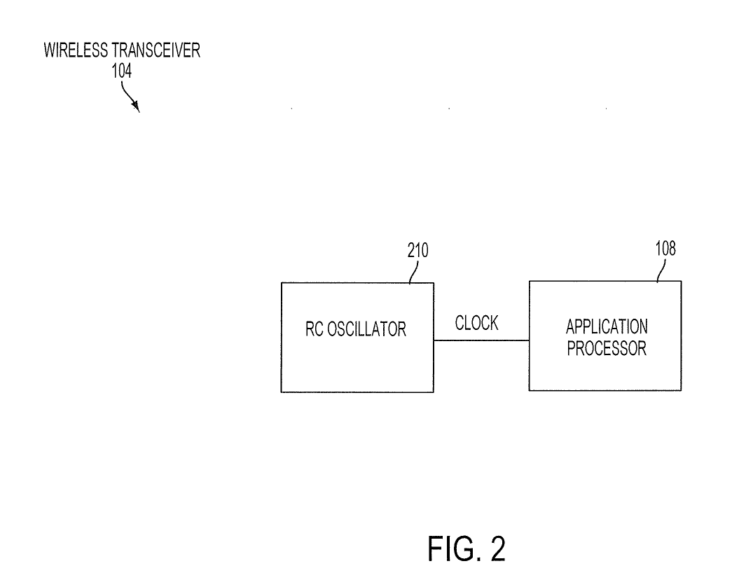

FIG. 2 is a block diagram of an RC oscillator generating a processor clock of the application processor. Various embodiments of an RC oscillator are presented, which may be used for various functions in the wireless device 100. FIG. 2 illustrates an example of using an RC oscillator 210 to generate the processor clock for the application processor 108. In another implementation, the application processor 108 may incorporate the RC oscillator 210 for generating clocks locally for various parts of the application processor 108. For the application processor 108, it would be advantageous for the clock to start at the operating oscillating frequency (e.g., no settling time). The feature would allow the application processor 108 to begin operating at a stable frequency substantially immediately. While examples of the RC oscillator are provided as parts of a wireless device and a wireless communication system, the applications of the disclosed RC oscillator are not limited thereto as would be appreciated by a person of ordinary skill in the art.

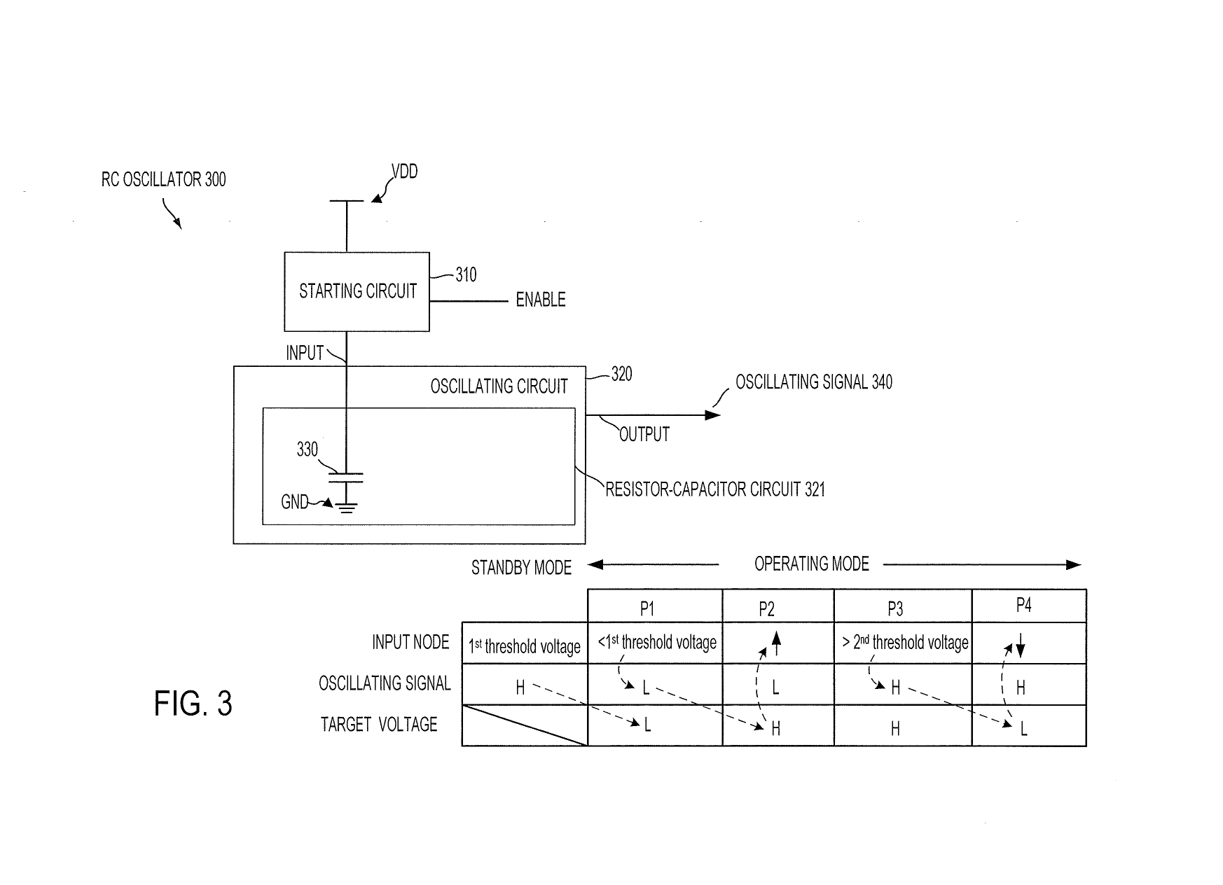

FIG. 3 is a block diagram illustrating an exemplary embodiment of an RC oscillator 300. The various blocks/circuits provide the means to perform the various functions of the exemplary embodiment. The RC oscillator 300 includes an oscillating circuit 320. The oscillating circuit 320 provides the means for generating an oscillating signal 340 at an oscillating frequency. The oscillating circuit 320 includes an input (the INPUT node) and an output. The oscillating circuit 320 generates the oscillating signal 340 (e.g., a signal that changes states at an oscillating frequency) on the output. The oscillating circuit 320 includes a resistor-capacitor circuit 321, which includes a capacitor 330. The INPUT node is coupled to a capacitor 330. Thus, in this example, the voltage at the INPUT node corresponds to the voltage of the capacitor 330. The capacitor 330 is further coupled to a reference voltage such as ground (GND). In one example, oscillating frequency of the RC oscillator 300 is based in part on the capacitance of the capacitor 330. The oscillating circuit 320 may be configured such that the oscillating signal 340 at the output of the oscillating circuit 320 transitions between states in response to the INPUT node reaching a threshold voltage. The resistor-capacitor circuit 321 is configured to bias the INPUT node towards a target voltage in response to the oscillator circuit output transitioning between the states.

The RC oscillator 300 further includes a starting circuit 310 selectively coupling a power source VDD to the input of the oscillating circuit 320 (the INPUT node). In one example, the power source VDD is a voltage supply that provides a supply voltage. The starting circuit 310 provides the means for providing a threshold voltage to an input to the oscillating circuit 320 in a standby mode. In one example, the starting circuit 310 charges or sets the input (the INPUT node) of the oscillating circuit 320 to a threshold voltage in the standby mode. In one configuration, the starting circuit 310 includes a switching circuit that couples a supply voltage (e.g., VDD) to the INPUT node of the oscillating circuit 320, which sets the input (the INPUT node) of the oscillating circuit 320 to a threshold voltage in the standby mode as described below. In one configuration, the starting circuit 310 may be configured to couple the supply voltage (e.g., VDD) from the INPUT node of the oscillating circuit 320 in the standby mode or to decouple the supply voltage (e.g., VDD) from the INPUT node of the oscillating circuit 320 to start the oscillating circuit 320, in response to the ENABLE signal. In one example, an activation of the ENABLE signal (e.g., going to a high state) may decouple the supply voltage (e.g., VDD) from the INPUT node of the oscillating circuit 320 and exit the standby mode. The ENABLE signal may be an asynchronous signal.

As described below, the oscillating circuit 320 is configured to initialize the oscillation of the oscillating signal 340 in synchronization with the ENABLE signal changing states, and initialize the oscillation at the oscillation frequency. The starting circuit 310 may be configured to set the INPUT node (the oscillating circuit input) to the threshold voltage to start the oscillating circuit 320. In one example, the RC oscillator 300 may thus be able to generate a precise clock at a known and stable frequency from the start, effectively providing “instant-start” of the RC oscillator 300. In another example, a charge pump controlling the RC oscillator 300 may exercise precise control of the charges to be inputted into the voltage input (for operating a VCO).

In one example, the starting circuit 310, by operating with the oscillating circuit 320, sets the input (the INPUT node) of the oscillating circuit 320 to a first threshold voltage in the standby mode and sets the oscillating signal 340 to a high state (e.g., VDD). The INPUT node does not have a target voltage in the standby mode as the RC oscillator 300 is in a stable or non-oscillating state. In the operating mode, at P1, the oscillating circuit 320 (e.g., via the resistor-capacitor circuit 321) bias the INPUT node toward a low target voltage (“L”), as a result of the oscillating signal 340 being at the high state. In one example, a target voltage is a final or settled voltage of the INPUT node if, e.g., the INPUT node is disconnected from the input of the oscillating circuit 320. The INPUT node voltage starts to drop toward the low target voltage. For example, the oscillating circuit 320 discharges the INPUT node toward the low target voltage (“L”). Because the INPUT node is set to the first threshold voltage in the standby mode, the INPUT node drops to below first threshold voltage almost instantaneously in the operating mode at P1, and, in response, the oscillating circuit 320 transitions the oscillating signal 340 to a low state (e.g., GND). At P2, in response to the oscillating signal 340 transitioning to the low state, the oscillating circuit 320 (e.g., via the resistor-capacitor circuit 321) bias the target voltage of the INPUT node toward a high voltage (“H”). The voltage of the INPUT node follows the high target voltage and rises toward the target voltage. For example, the oscillating circuit 320 charges the INPUT node toward the high target voltage (“H”). The rise of the voltage of the INPUT node is subject to the RC constant based in part on the capacitance of the capacitor 330. The oscillating signal 340 remains at the low state while the voltage of the INPUT node is in transition. At P3, the voltage of the INPUT node reaches the second threshold voltage (but before reaching the high target voltage H). In response, the oscillating circuit 320 transitions the oscillating signal 340 to the high state. At P4, in response to transitioning the oscillating signal 340 to the high state, the oscillating circuit 320 (e.g., via the resistor-capacitor circuit 321) bias the target voltage of the INPUT node toward the low target voltage (“H”). The voltage of the INPUT node follows the low target voltage and discharges toward the target voltage. For example, the oscillating circuit 320 discharges the INPUT node toward the low target voltage (“L”). The discharge of the voltage of the INPUT node is subject to the RC constant based in part on the capacitance of the capacitor 330. The oscillating signal 340 remains at the high state while the voltage of the INPUT node is in transition. Subsequently, the operation of the RC oscillator 300 returns to P1.

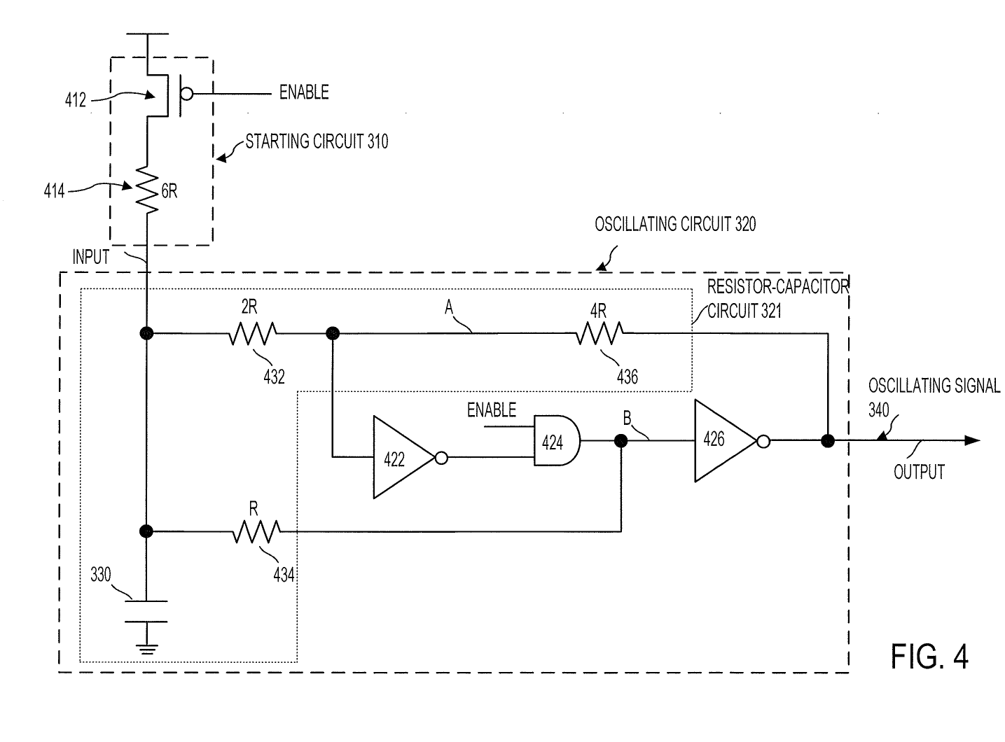

FIG. 4 is a circuit diagram illustrating an exemplary embodiment of an RC oscillator. The starting circuit 310 includes a p-type transistor 412 and a resistor (e.g., a resistive element) 414. The p-type transistor 412 is controlled by the ENABLE signal. In the standby mode, the ENABLE signal is in a low state (e.g., GND) and turns on the p-type transistor 412. Thus, in the standby mode, the power source VDD charges the INPUT node and the capacitor 330 via the p-type transistor 412 and the resistor 414. The resistor 414 may have a resistance value of 6R (e.g., the resistance of the resistor 414 is six times the resistance of a reference resistance R). As will be shown below, the starting circuit 310, in combination with operating the oscillating circuit 320, charges the INPUT node (and the capacitor 330) to a level of VDD×¼R. Moreover, in the standby state, the ENABLE signal is in the low state and drives the oscillating signal 340 to the high state (e.g., VDD) via the AND gate 424 and the inverter 426.

The oscillating circuit 320 includes an inverter (e.g. inverting circuit) 422 and an inverter 426 coupled via an AND gate 424. In one example, the inverter 422 may include several inverters in series. There may be multiple stages of logic elements and gates (not shown) between the inverter 422 and the inverter 426 at least for timing purpose. The inverter 422 receives input at node A. In this example, the inverter 422 is configured to have a switch point at a midpoint of VDD (VDD/2). In combination with the resistors 432 and 436, the INPUT node causes the inverter 422 to change state at a first threshold voltage of VDD×¼R and a second threshold voltage of VDD×¾R (e.g., the inverter 422 switches states when the INPUT node reaches the threshold voltages). When the INPUT node reaches the first threshold voltage VDD×¼R while discharging, the output of the AND gate 424 is switched to a high state (e.g., VDD), and the oscillating signal 340 is switched to a low state (e.g., GND). When the INPUT node reaches the second threshold voltage VDD×¾R while charging, the output of the AND gate 424 is switched to a low state (e.g., GND), and the oscillating signal 340 is switched to a high state (e.g., VDD). The AND gate 424 receives input from the ENABLE signal and the inverter 422, and outputs to the node B. The inverter 426 receives input from node B and outputs the oscillating signal 340.

The oscillating circuit 320 includes the resistor-capacitor circuit 321, via which the inverter 422 and the inverter 426 are coupled to the INPUT node (and capacitor 330). In one example, the resistor-capacitor circuit 321 is passive as the circuit itself is not coupled to any active power supply; the resistor-capacitor circuit 321 is only coupled to the power supply VDD via other circuits, such as the starting circuit 310 and the inverters 422 and 426. The resistor-capacitor circuit 321 includes resistors (resistive elements) 432, 436, and 434. In the example, the resistor 432 has a resistance of 2R; the resistor 436 has a resistance of 4R; and the resistor 434 has a resistance of R. The oscillating signal 340 is coupled to the INPUT node (and capacitor 330) via the resistors 432 and 436 arranged in series. The input of the inverter 422 is coupled to both the resistors 432 and 436 at node A. The output of the inverter 422 is coupled to the INPUT node (and capacitor 330) via node B and the resistor 434.

The starting circuit 310, by operating with the oscillating circuit 320, sets the input (the INPUT node) of the oscillating circuit 320 to a first threshold voltage in the standby mode. In the standby mode, the oscillating signal 340 is in a high state (e.g., VDD), and the node B is in a low state (e.g., GND). In this configuration, the resistor-capacitor circuit 321, in combination with the starting circuit 310, operates as a voltage divider. The power source VDD is coupled to the INPUT node via the inverter 426 and the oscillating signal 340. Further, the power source VDD from the oscillating signal 340 to the INPUT node has a resistance of 6R (the resistance 2R of the resistor 432 plus the resistance 4R of the resistor 436). In parallel, the power source VDD is coupled to the INPUT node via the resistance of 6R of the resistor 414 of the starting circuit 310. Thus, the power source VDD is coupled to the INPUT node at an equivalent resistance of 3R. The INPUT node is also coupled to GND via a resistance of R (resistor 434). Accordingly, the total resistance from VDD to GND in the standby mode is 4R (the equivalent resistance 3R plus the resistance R of the resistor 434). Thus, in the standby mode, the INPUT node is charged to VDD×¼R, which corresponds to the first threshold voltage.

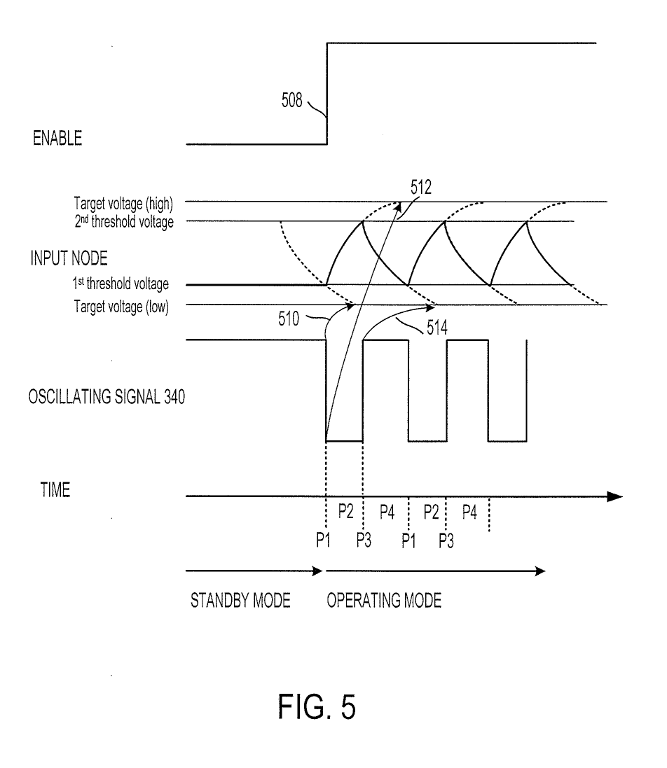

FIG. 5 is a diagram of waveforms of an exemplary embodiment in operation. At 508, the ENABLE signal goes to a high state (e.g., VDD), and, in response, the RC oscillator 300 enters into the operating mode. At P1, referring to FIG. 4, upon the ENABLE signal going to the high state, the starting circuit 310 is disabled (decoupled from the oscillating circuit 320). Thus, the power source VDD (at the oscillating signal 340) is coupled to the INPUT node via a resistance of 6R (the resistance 2R of the resistor 432 plus the resistance 4R of the resistor 436), and the INPUT node is coupled to GND via a resistance of R (resistor 434). The total resistance from the power source VDD to GND is thus 7R, and the target voltage of the INPUT node, as biased by the resistor-capacitor circuit 321 and the inverters 422 and 426, stands at a voltage of VDD× 1/7R (at 510). Thus, the low target voltage of the INPUT node is lower than the first threshold voltage of the INPUT node. Accordingly, the voltage of the INPUT node follows the low target voltage and drops below the first threshold voltage of VDD×¼R (e.g., crosses the first threshold voltage). In response, the inverters 422 and 426 switch states, and the inverter 426 transitions the oscillating signal 340 to a low state. The target voltage at the INPUT node changes as soon as the ENABLE signal changes states (going from the low state in the standby mode to the high state). Thus, the oscillating signal 340 is initialized in synchronization with the ENABLE signal changing states.

At P2, in response to the low state of the oscillating signal 340, the oscillating circuit 320 (e.g., via the resistor-capacitor circuit 321) bias the target voltage of the INPUT node toward a high voltage 512 (a high target voltage), as described below. When the oscillating signal 340 is at the low state or GND, the node B is at the high state or VDD. The power source VDD at node B is thus coupled to the INPUT node (and the capacitor 330) via a resistance of R of the resistor 434. The INPUT node (and the capacitor 330) is coupled to GND at the oscillating signal 340 via a resistance of 6R (the resistance 2R of the resistor 432 plus the resistance 4R of the resistor 436). Thus, the total resistance from VDD to GND is 7R, and the voltage divider of the resistors 432, 434, and 436 sets the target voltage at the INPUT node at VDD× 6/7R. Thus, the high target voltage of the INPUT node is higher than the second threshold voltage. The voltage of the INPUT node follows the high target voltage and rises toward the target voltage. For example, the oscillating circuit 320 charges the INPUT node (e.g., via the AND gate 424). The rise of the voltage of the INPUT node is subject to the RC constant based in part on the capacitance of the capacitor 330. The oscillating signal 340 remains at the low state while the voltage of the INPUT node is in transition.

At P3, the voltage of the INPUT node reaches the second threshold voltage VDD×¾R (e.g., crosses the first threshold voltage) before reaching the high target voltage. In response, the oscillating circuit 320 transitions the oscillating signal 340 to the high state. At P4, in response to transitioning the oscillating signal 340 to the high state, the oscillating circuit 320 (e.g., via the resistor-capacitor circuit 321) bias the target voltage of the INPUT node toward a low voltage 514 (the low target voltage), as described below.

When the oscillating signal 340 is at the high state or VDD, the node B is at the low state or GND. The power source VDD at the oscillating signal 340 is thus coupled to the INPUT node (and the capacitor 330) via a resistance of 6R (the resistance 2R of the resistor 432 plus the resistance 4R of the resistor 436). The INPUT node (and the capacitor 330) is coupled to GND at the node B via a resistance of R of the resistor 434. Thus, the total resistance from VDD to GND is 7R, and the voltage divider of the resistors 432, 434, and 436 sets the target voltage at the INPUT node at VDD× 1/7R. The voltage of the INPUT node follows the low target voltage and discharges toward the target voltage. For example, the oscillating circuit 320 discharges the INPUT node by (e.g., via the AND gate 424). The rise of the voltage of the INPUT node is subject to the RC constant based in part on the capacitance of the capacitor 330. The oscillating signal 340 remains at the high state while the voltage of the INPUT node is in transition. Subsequently, the operation of the RC oscillator 300 returns to P1.

As shown above, in one aspect, the voltage at the INPUT node and the capacitor 330 oscillates between the first threshold voltage and the second threshold voltage. Because the starting circuit 310 sets the voltage at the INPUT node to the first threshold voltage (in combination with operating the oscillating circuit 320), the oscillating circuit 320 starts the oscillation at the operating oscillating frequency. As illustrated in FIG. 5, the operating oscillation frequency may be 1 over the period of P1+P2+P3+P4 (1/P1+P2+P3+P4). In other words, the operation of the oscillating signal 340 requires no settling time to reach the operating oscillating frequency, allowing it to begin operating at a stable frequency substantially instantly when the ENABLE signal goes high. In one example, the initial state transition time P1-P3 corresponds to the operating frequency of the oscillating signal 340. Moreover, no clocks are required to operate the oscillating circuit 320 to start at the operating frequency. Thus, the ENABLE signal may be an asynchronous signal, and no clocks are provided to the RC oscillator 300. Moreover, as describe with P1 of FIGS. 3 and 5, the oscillation of the oscillating signal 340 is synchronized with the ENABLE signal changing its states.

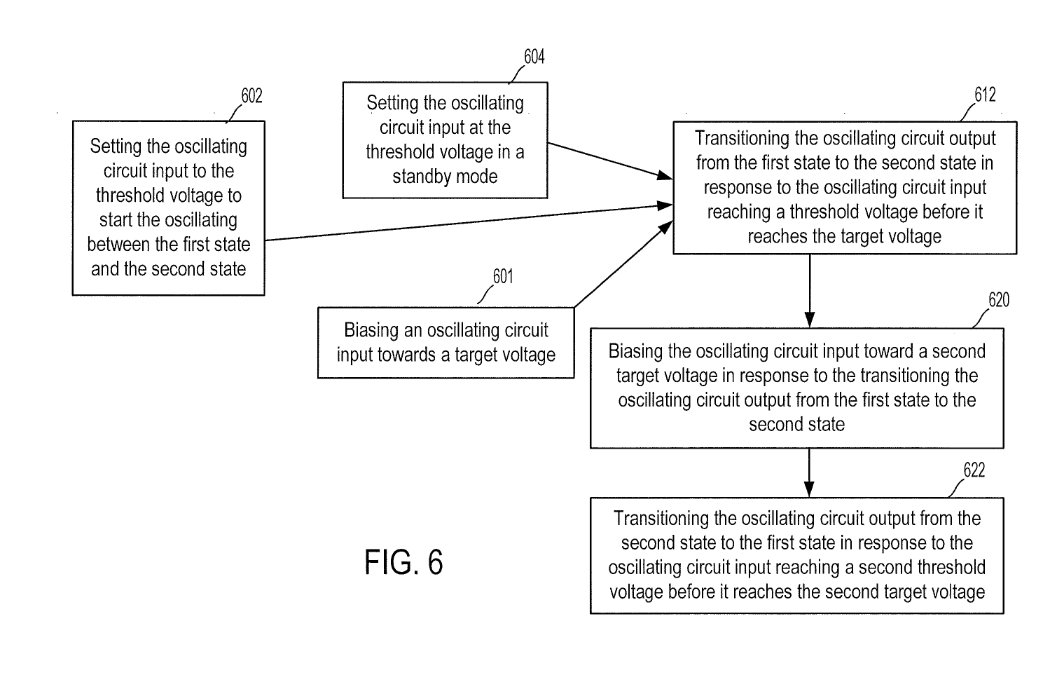

FIG. 6 is a flowchart of an exemplary embodiment of an RC oscillator in operation. Some of the steps shown in may be optional. At 601, an oscillating circuit input is bias towards a target voltage. See, e.g., FIGS. 3-5 and the accompanying text. For example, FIG. 5 illustrates that the input (INPUT node) of the oscillating circuit 320 is bias toward a low targeting voltage (e.g., at P1). At 602, the oscillating circuit input is set to the threshold voltage to start the oscillating between a first state and the second state. At 604, the oscillating circuit input is set at the threshold voltage in a standby mode. See, e.g., FIGS. 3-5 and the accompanying text describing the starting circuit 310 setting the INPUT node at the first threshold voltage based on the ENABLE signal, which may be an asynchronous signal. See, e.g., FIG. 5 illustrating that the oscillating starts at the first threshold voltage at time P1.

At 612, the oscillating circuit output is transitioned from the first state to the second state in response to the oscillating circuit input reaching the threshold voltage before it reaches the target voltage. See, e.g., FIGS. 3-5 and the accompanying text. For example, FIG. 5 illustrates that the output of the oscillating circuit 320 (the oscillating signal 340) transitions at P1 from the high state to the low state in response to the INPUT node reaching the first threshold voltage before reaching the low target voltage.

At 620, the oscillating circuit input is biased toward a second target voltage in response to the transitioning the oscillating circuit output from the first state to the second state. See, e.g., FIGS. 3-5 and the accompanying text. For example, FIG. 5 illustrates that the INPUT node is biased (at P2) to the high target voltage in response to the oscillating signal 340 transitioning from the high state to the low state. At 622, the oscillating circuit output is transitioned from the second state to the first state in response to the oscillating circuit input reaching a second threshold voltage before it reaches the second target voltage. See, e.g., FIGS. 3-5 and the accompanying text. For example, FIG. 5 illustrates that the oscillating circuit output (the oscillating signal 340) transitions from the low state to the high state (at P3) in response to the oscillating circuit input (the INPUT node) reaching the second threshold voltage before it reaches the high target voltage.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The previous description is provided to enable any person skilled in the art to fully understand the full scope of the disclosure. Modifications to the various exemplary embodiments disclosed herein will be readily apparent to those skilled in the art. Thus, the claims should not be limited to the various aspects of the disclosure described herein, but shall be accorded the full scope consistent with the language of claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. An oscillator, comprising:
an oscillating circuit having an input and an output configured to oscillate between a first state and a second state, wherein the oscillating circuit comprises a resistor-capacitor circuit configured to bias the oscillating circuit input towards a target voltage, and
wherein the oscillating circuit is configured to transition the oscillating circuit output from the first state to the second state in response to the oscillating circuit input reaching a threshold voltage before the oscillating circuit input reaches the target voltage.

2. The oscillator of claim 1, further comprising a starting circuit configured to set the oscillating circuit input at the threshold voltage in a standby mode.

3. The oscillator of claim 2, wherein the starting circuit is configured to set the oscillating circuit input at the threshold voltage in the standby mode by operating with the oscillating circuit, which functions as a voltage divider.

4. The oscillator of claim 2, wherein the starting circuit is configured to receive an asynchronous signal, wherein the starting circuit is configured to couple to the oscillating circuit in the standby mode or to decouple from the oscillating circuit based on the asynchronous signal.

5. The oscillator of claim 4, wherein the oscillating circuit is configured to receive the asynchronous signal, and wherein the oscillating circuit is configured to transition the oscillating circuit output from the first state to the second state in response to an activation of the asynchronous signal.

6. The oscillator of claim 5, wherein the oscillating circuit is configured to transition the oscillating circuit output from the first state to the second state by the resistor-capacitor circuit biasing the oscillating circuit input toward the target voltage in response to the activation of the asynchronous signal.

7. The oscillator of claim 6, wherein the oscillating circuit is configured to transition the oscillating circuit output from the first state to the second state by charging or discharging the oscillating circuit input toward the target voltage in response to the resistor-capacitor circuit biasing the oscillating circuit input toward the target voltage.

8. The oscillator of claim 7, wherein the resistor-capacitor circuit is configured to bias the oscillating circuit input toward a second target voltage in response to the oscillating circuit output transitioning from the first state to the second state upon the oscillating circuit input reaching the threshold voltage before the oscillating circuit input reaches the target voltage.

9. The oscillator of claim 8, wherein the oscillating circuit is configured to charge or discharge the oscillating circuit input toward the second target voltage in response to the resistor-capacitor circuit biasing the oscillating circuit input toward the second target voltage.

10. The oscillator of claim 9, wherein the oscillating circuit is configured to transition the oscillating circuit output from the second state to the first state in response to the oscillating circuit input reaching a second threshold voltage before it reaches the target voltage.

11. The oscillator of claim 1, wherein the oscillating circuit comprises at least one inverting circuit having an input and an output, and wherein the resistor-capacitor circuit comprises a capacitive element coupled to the oscillating circuit input.

12. The oscillator of claim 11, wherein the capacitive element is coupled to the input and the output of the at least one inverting circuit via at least one resistor.

13. An oscillator, comprising:
an oscillating circuit having an input and an output configured to oscillate between first and second states, wherein the oscillating circuit is configured to transition the oscillating circuit output from the first state to the second state in response to the oscillating circuit input reaching a threshold voltage; and
a starting circuit configured to set the oscillating circuit input to the threshold voltage to start the oscillating circuit.

14. The oscillator of claim 13, wherein the starting circuit is configured to set the oscillating circuit input at the threshold voltage by operating with the oscillating circuit, which functions as a voltage divider.

15. The oscillator of claim 14, wherein the starting circuit is configured to receive an asynchronous signal, wherein the starting circuit is configured to couple to the oscillating circuit or to decouple from the oscillating circuit to start the oscillating circuit in response to the asynchronous signal.

16. The oscillator of claim 15, wherein the oscillating circuit is configured to receive the asynchronous signal, and wherein the oscillating circuit is configured to transition the oscillating circuit output from the first state to the second state in response to an activation of the asynchronous signal.

17. The oscillator of claim 14, wherein the oscillating circuit comprises a resistor-capacitor circuit configured to bias the oscillating circuit input to a target voltage, and
wherein the oscillating circuit is configured to transition the oscillating circuit output from the first state to the second state in response to the oscillating circuit input reaching the threshold voltage before the oscillating circuit input reaches the target voltage.

18. The oscillator of claim 17, wherein the oscillating circuit is configured to transition the oscillating circuit output from the first state to the second state by charging or discharging the oscillating circuit input toward the target voltage in response to the oscillating circuit biasing the oscillating circuit input toward the target voltage.

19. The oscillator of claim 18, wherein the oscillating circuit is configured to oscillate the oscillating circuit at a frequency, and to transition the oscillating circuit output from the second state to the first state at the frequency.

20. The oscillator of claim 19, wherein the oscillating circuit is configured to bias the oscillating circuit input toward a second target voltage in response to the oscillating circuit output transitioning from the first state to the second state, and to charge or discharge the oscillating circuit input toward the second target voltage in response to the oscillating circuit biasing the oscillating circuit input toward the second target voltage.

21. The oscillator of claim 20, wherein the oscillating circuit is configured to transition the oscillating circuit output from the second state to the first state in response to the oscillating circuit input reaching a second threshold voltage before it reaches the second target voltage at the frequency.

22. The oscillator of claim 13, wherein the oscillating circuit comprises:
at least one inverting circuit having an input and an output; and
a resistor-capacitor circuit comprising a capacitive element, wherein the capacitive element is coupled to the oscillating circuit input.

23. The oscillator of claim 22, wherein the capacitive element is coupled to the input and the output of the at least one inverting circuit via at least one resistor.

24. A method of operating an oscillating circuit having an input and an output configured to oscillate between a first state and a second state, comprising:
biasing the oscillating circuit input towards a target voltage;
transitioning the oscillating circuit output from the first state to the second state in response to the oscillating circuit input reaching a threshold voltage before the oscillating circuit input reaches the target voltage; and
setting the oscillating circuit input at the threshold voltage in a standby mode.

25. The method of claim 24, further comprising biasing the oscillating circuit input toward a second target voltage in response to the transitioning the oscillating circuit output from the first state to the second state.

26. The method of claim 25, further comprising transitioning the oscillating circuit output from the second state to the first state in response to the oscillating circuit input reaching a second threshold voltage before the oscillating circuit input reaches the second target voltage.

27. A method of operating an oscillating circuit having an input and an output configured to oscillate between first and second states, comprising:
setting the oscillating circuit input to a threshold voltage to start the oscillating between the first state and the second state; and
transitioning the oscillating circuit output from the first state to the second state in response to the oscillating circuit input being set at the threshold voltage.

28. The method of claim 27, further comprising biasing the oscillating circuit input to a target voltage, and
wherein the transitioning the oscillating circuit output from the first state to the second state being in response to the oscillating circuit input reaching the threshold voltage before the oscillating circuit input reaches the target voltage.

29. The method of claim 28, further comprising biasing the oscillating circuit input toward a second target voltage in response to the transitioning the oscillating circuit output from the first state to the second state.
